(19) United States
(12) Patent Application Publication
(10) Pub. No.: US 2016/0099677 A1
(43) Pub. Date: Apr. 7, 2016

(54) CRYSTAL OSCILLATOR CIRCUIT WITH REDUCED STARTUP TIME

(71) Applicants: Advanced Micro Devices, Inc., Sunnyvale, CA (US); ATI Technologies ULC, Markham (CA)

(72) Inventors: Saeed Abbasi, Valley Forge, PA (US); Jun Hong Zhao, Toronto (CA); Raymond S.P. Tam, Richmond Hill (CA); James Lin, Richmond Hill (CA); Michael R. Foxcroft, Toronto (CA)

(21) Appl. No.: 14/507,521

(22) Filed: Oct. 6, 2014

(51) Int. Cl. H03B 5/06; H03B 5/32

(52) U.S. Cl. CPC H03B 5/06; H03B 5/32

(57) ABSTRACT

A crystal oscillator achieves fast start-up by injecting an in-band periodic signal into the crystal oscillator driver circuit. The in-band periodic signal has a frequency that is within a bandwidth of the crystal oscillator. Injection of the in-band periodic signal begins in response to a power-up condition and stops after a predetermined time period corresponding to the amount of time it takes to ensure the crystal driver is achieving full swing.

### BACKGROUND

1. Field of the Invention

The invention relates to crystal oscillators and more particularly to start-up time associated with crystal oscillators.

2. Description of the Related Art

Crystal oscillators are well known in the art to provide timing signals for a wide variety of applications. FIG. 1 shows a high level diagram of a crystal oscillator circuit 100 that includes a crystal 101 and a crystal driver circuit that includes inverter 103 as a gain stage. Note that the driver circuit functions as a loop circuit and feeds back its output to the crystal 101. The crystal driver circuit is typically located on an integrated circuit while the crystal is located off-chip. The crystal supplies an oscillating signal to the inverter 103 through the input terminal shown as XTALIN. The crystal is also coupled to receive the output of the inverter 103 as a feedback signal through the output terminal XTALOUT. During a power-up operation, the crystal oscillator takes a finite amount of time before the oscillator signal reaches full swing, which generally indicates that the oscillator signal is ready for use as a timing signal by other circuitry in the integrated circuit. Before the signal reaches full swing, the oscillator signal may be too small to be used by other circuitry in the integrated circuit.

### SUMMARY OF EMBODIMENTS OF THE INVENTION

Accordingly, in one embodiment a method includes in response to a first condition, injecting an in-band periodic signal into a crystal oscillator driver circuit, the in-band signal having a frequency within a bandwidth of a crystal oscillator, the crystal oscillator including a crystal and the crystal oscillator driver circuit.

In another embodiment, an apparatus includes a crystal oscillator driver circuit. An in-band periodic signal generator is coupled to inject an in-band periodic signal into an input of the driver circuit, the in-band periodic signal having a frequency within a bandwidth of a crystal oscillator, the crystal oscillator including a crystal and the crystal oscillator driver circuit.

In another embodiment, an apparatus includes a crystal oscillator, which includes a crystal and a crystal oscillator driver circuit. An in-band periodic signal generator is coupled to inject an in-band periodic signal into the crystal oscillator driver circuit, the in-band periodic signal having a frequency within a bandwidth of the crystal oscillator.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a high level diagram of a crystal oscillator.

FIG. 2 illustrates a high level diagram of a crystal oscillator circuit according to an embodiment.

FIG. 3 illustrates additional detail of control and generation of an in-band periodic signal.

FIG. 4 illustrates an embodiment of an in-band periodic signal generator implemented as a ring oscillator.

FIG. 5 illustrates an embodiment of a crystal oscillator circuit with the capability to inject an in-band periodic signal.

FIG. 6 illustrates an embodiment of an inverter that may be used as a gain element in the drive circuit of the crystal oscillator.

The use of the same reference symbols in different drawings indicates similar or identical items.

### DETAILED DESCRIPTION

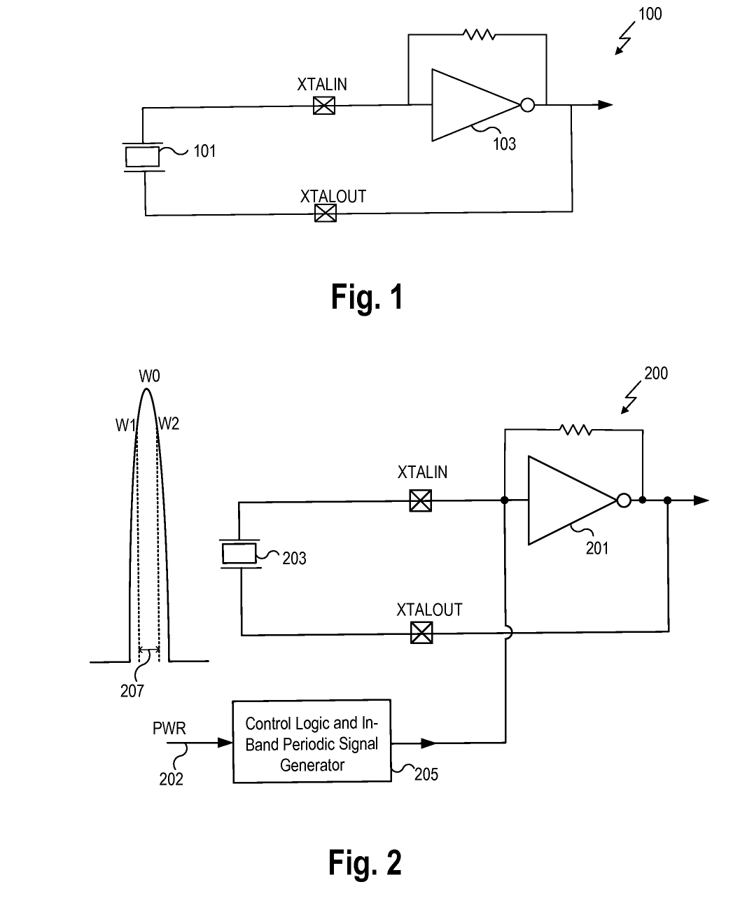

FIG. 2 illustrates a high level diagram of a crystal oscillator circuit 200 according to an embodiment. The crystal oscillator circuit 200 injects an in-band periodic signal in the crystal oscillator driver loop. One desirable aspect of a clock signal generated using a crystal oscillator is to have low noise. One way to contribute to low noise is to use a crystal having a very high quality factor (Q) value that leads to narrow bandwidth operation. However, having a narrow bandwidth can increase the time for the crystal driver to achieve full swing. Because fast start-up is desirable in many electronic systems, the embodiment in FIG. 2 injects an in-band periodic signal into the crystal loop circuit at the input of the crystal driver to achieve full swing faster at the driver to speed start-up of the crystal oscillator.

In an embodiment in the power up mode, the input and output of the driver is biased to half of the supply voltage. The in-band noise in the crystal driver loop is very small because the bandpass characteristics of the crystal are amplified by the driver as the driver approaches full swing. Full swing refers to the difference between maximum and minimum voltages in the oscillating signal at the output of the crystal driver circuit once steady state operation is achieved. Initially the amplitude of the oscillating signal is small and grows larger during startup until full swing is achieved.

The center frequency of the crystal oscillator is described by

$${W}_{0} = \frac{1}{\sqrt{LC}} .$$

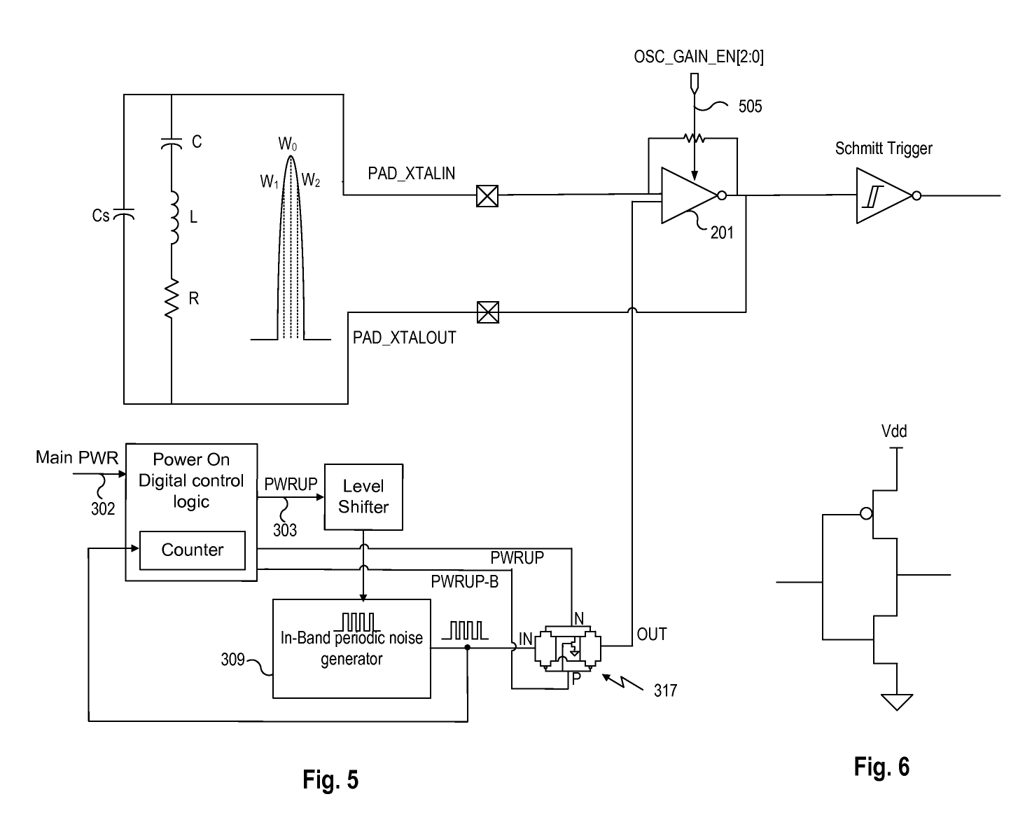

The quality factor Q is the peak energy stored in L or C per cycle over the energy dissipated in R per cycle (see L, C, and R in FIG. 5). The smaller R leads to higher Q and narrower bandwidth and longer startup times.

$$Q = \frac{{W}_{o} L}{R} = \frac{1}{R} \sqrt{\frac{L}{C}}$$

$${W}_{1} = {W}_{0} - \frac{{W}_{o}}{2 Q}$$

$${W}_{2} = {W}_{0} + \frac{{W}_{o}}{2 Q}$$

The bandwidth of the crystal is

$$β = {W}_{2} - {W}_{1} = \frac{R}{L} .$$

As can be seen, as the quality factor Q goes up, the bandwidth narrows. A startup circuit providing an in-band periodic signal reduces the amount of time the signal provided by inverter 201 takes to reach full swing.

Referring to the embodiment of FIG. 2, the input of the inverter 201 is coupled to the output terminal of the crystal 203 and the output of the inverter 201 feeds back to the crystal 203. The inverter functions as a gain stage in the crystal driver circuit that includes the resistor and inverter 201. In response to a power up signal indicated on signal line 202, the in-band signal generator and control logic 205 supplies an in-band signal to the input of the inverter 201. The term in-band refers to a signal having a frequency that is within the bandwidth β=W₂−W₁ of the crystal oscillator 200 shown graphically in FIG. 2 as bandwidth 207.

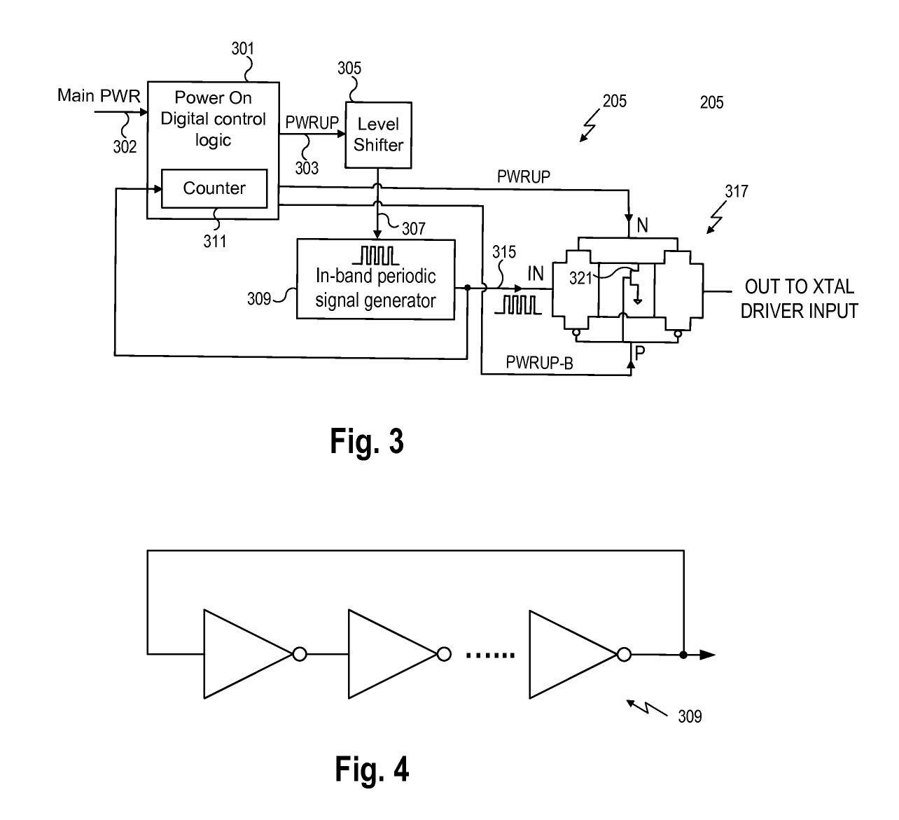

FIG. 3 illustrates additional details of an embodiment of the in-band signal generator and control logic 205. The control logic 301 detects when the power-up condition exists, e.g., based on a rising edge of the MAIN PWR signal 302. When that condition is recognized, the control logic provides a PWR signal 303 to level shift circuit 305. The level shift circuit 305 supplies a power supply signal 307, based on the main supply voltage, to the in-band periodic signal generator 309. In some embodiments, the voltage level may be shifted, e.g., higher or lower than the main supply voltage, and in other embodiments, the voltage supplied on node 307 is the same as the main supply voltage and a switch may be used to couple the supply voltage to the in-band periodic signal generator 309. When the in-band periodic signal generator 309 receives the power supply signal 307, the in-band periodic signal generator 309 begins to generate a periodic signal having a frequency that is within the bandwidth of the crystal oscillator circuit. For example, the crystal oscillator circuit may be designed to have a center frequency of 48 MHz with a bandwidth of 100 KHz. The in-band periodic signal generator 309 may in turn be designed to oscillate at a frequency of 48 MHz. The particular frequency chosen for the in-band signal generator of course depends on the crystal oscillator circuit with which it operates. As shown in FIG. 4, the in-band periodic signal generator 309 may be implemented as a ring oscillator.

Once the periodic signal generator begins to supply the in-band signal, that signal is supplied to counter 311. Counter 311 tracks the length of time that the in-band signal is injected into the crystal driver loop at the input of the crystal driver. The counter 311 is coupled to receive the periodic in-band signal 315 supplied by the periodic signal generator 309 and uses the in-band signal to increment (or decrement) its count. The counter may be clocked directly by the periodic in-band signal or be clocked by a signal derived from the periodic in-band signal, e.g., to reduce the clock rate.

The periodic in-band signal 315 is coupled to the input of the crystal driver through a transmission gate or switch 317. The control logic turns on the N-channel and P-channel transistors of the transmission gate or switch to couple the periodic signal to the input of the inverter. The switch turns in response to power-up and the switch turns off when the counter has reached a predetermined value, e.g., by counting up or counting down a predetermined amount. In an embodiment, the counter counts a value that corresponds to the crystal driver achieving full swing. In an embodiment, that length of time is approximately 2 microseconds but in other embodiments the time will vary according to the particular embodiment, e.g., on the gain of the gain stage. Note that once the counter has determined that the crystal driver is operating at full swing (the output of inverter 201) based on the count expiring, the crystal driver is isolated from the circuits that inject the periodic in-band signal by grounding the transmission gate through transistor 321 and turning off the N-channel and P-channel transistors constituting the transmission gate.

FIG. 5 shows another high level view of an embodiment of a crystal oscillator circuit having in-band periodic signal injected into the crystal driver to achieve faster full ramp operation. In FIG. 5 the crystal oscillator is represented by C, L, R, and Cs, where Cs is the shunt capacitance, C represents the motional capacitance, R represents the series resistance, and L represents the motional inductance. In response to the power up signal (PWRUP), the in-band period signal generator 309 generates the in-band signal 315, which is supplied to transmission gate 317. In addition, the power up signal is supplied to turn on the NMOS transistors in transmission gate 317 and the power up bar (PWRUP-B) signal is supplied to turn on the PMOS transistors in the transmission gate. FIG. 5 also shows that the gain element 201 may be adjustable through the gain enable signal 505.

Another aspect of the gain element 201 is that the transistors forming the gain element may be designed for increased gain and reduced power consumption during start-up. For an inverter, such as shown in FIG. 6, setting the gate voltages of the PMOS and NMOS transistors to both be on, e.g., at Vdd/2, results in both transistors conducting current and the current shoots through the two transistors to ground. That shoot through current is undesirable as it results in wasted power consumption. In one embodiment the length of the channel of the transistors in the inverter is increased to reduce current shoot through and increase the gain of the gain element. Note that too large an increase in L can result in decreased gain. The optimal design of the gain element depends on the particular technology in which the circuit is built, the desired gain, and the power budget.

While circuits and physical structures have been generally presumed in describing embodiments of the invention, it is well recognized that in modern semiconductor design and fabrication, physical structures and circuits may be embodied in a computer readable medium as data structures for use in subsequent design, simulation, test, or fabrication stages. For example, such data structures may encode a functional description of circuits or systems of circuits. The functionally descriptive data structures may be, e.g., encoded in a register transfer language (RTL), a hardware description language (HDL), in Verilog, or some other language used for design, simulation, and/or test. Data structures corresponding to embodiments described herein may also be encoded in, e.g., Graphic Database System II (GDSII) data, and functionally describe integrated circuit layout and/or information for photomask generation used to manufacture the integrated circuits. Other data structures, containing functionally descriptive aspects of embodiments described herein, may be used for one or more steps of the manufacturing process.

Computer-readable media include tangible computer readable media, e.g., a disk, tape, or other magnetic, optical, or electronic storage medium. In addition to computer-readable medium having encodings thereon of circuits, systems, and methods, the computer readable media may store instructions as well as data that can be used to implement embodiments described herein or portions thereof. The data structures may be utilized by software executing on one or more processors, firmware executing on hardware, or by a combination of software, firmware, and hardware, as part of the design, simulation, test, or fabrication stages.

The description of the invention set forth herein is illustrative, and is not intended to limit the scope of the invention as set forth in the following claims. Other variations and modifications of the embodiments disclosed herein may be made based on the description set forth herein, without departing from the scope of the invention as set forth in the following claims.

What is claimed is:

1. A method comprising:
in response to a first condition, injecting an in-band periodic signal into a crystal oscillator driver circuit, the in-band signal having a frequency within a bandwidth of a crystal oscillator, the crystal oscillator including a crystal and the crystal oscillator driver circuit.

2. The method as recited in claim 1 wherein the first condition is a power-on condition.

3. The method as recited in claim 1 further comprising stopping injection of the in-band periodic signal into the crystal oscillator driver circuit after the crystal oscillator driver circuit achieves full swing.

4. The method as recited in claim 1 further comprising ending injecting the in-band periodic signal into the crystal oscillator driver circuit after a predetermined time period has expired.

5. The method as recited in claim 4 further comprising counting the predetermined time period using a counter circuit that counts based on the in-band periodic signal.

6. The method as recited in claim 1 further comprising turning off a transmission gate coupling the in-band periodic signal to an input of the crystal oscillator driver circuit in response to a predetermined time period expiring.

7. The method as recited in claim 1 further comprising injecting the in-band periodic signal into an input of the crystal oscillator driver circuit.

8. The method as recited in claim 1 further comprising enabling a bias circuit supplying power to the periodic signal generator in response to a power-up condition to thereby start generation of the in-band periodic signal.

9. An apparatus comprising:
a crystal oscillator driver circuit; and
an in-band periodic signal generator coupled to inject an in-band periodic signal into an input of the driver circuit, the in-band periodic signal having a frequency within a bandwidth of a crystal oscillator, the crystal oscillator including a crystal and the crystal oscillator driver circuit.

10. The apparatus as recited in claim 9 further comprising a switch circuit coupled between the input of the driver circuit and the in-band periodic signal generator.

11. The apparatus as recited in claim 10 further comprising control logic configured to stop injection of the in-band periodic signal into the crystal oscillator driver circuit after the crystal oscillator driver circuit achieves full swing.

12. The apparatus as recited in claim 9 further comprising control logic configured to stop injection of the in-band periodic signal after a predetermined time period has expired.

13. The apparatus as recited in claim 12 wherein the control logic supplies one or more control signals to the switch circuit to turn off the switch circuit to stop injection of the in-band periodic signal and isolate the driver circuit from the in-band periodic signal generator after the predetermined time period.

14. The apparatus as recited in claim 12 wherein the control logic is configured to control the in-band periodic signal generator to supply the in-band periodic signal in response to a power-up condition.

15. The apparatus as recited in claim 12 further comprising a bias circuit configured to supply a supply voltage to the periodic signal generator in response to the power-up condition.

16. The apparatus as recited in claim 12 wherein the control logic further comprises a counter circuit coupled to count the predetermined time period.

17. The apparatus as recited in claim 12 wherein the counter circuit is coupled to count based on the in-band periodic signal.

18. The apparatus as recited in claim 12 further comprising a crystal coupled at one terminal to the input of the driver circuit and coupled at another terminal to an output of the driver circuit.

19. The apparatus as recited in claim 9 wherein the crystal oscillator driver circuit comprises an inverter as a gain stage.

20. An apparatus comprising:
a crystal oscillator including a crystal and a crystal oscillator driver circuit;
an in-band periodic signal generator coupled to inject an in-band periodic signal into the crystal oscillator driver circuit, the in-band periodic signal being within a bandwidth of the crystal oscillator; and
control logic configured to start injection of the in-band periodic signal in response to a power-up condition and to stop the in-band periodic signal from being supplied to the crystal oscillator driver circuit after a predetermined time period.
